(19) United States
(12) Patent Application Publication
(10) Pub. No.: US 2025/0324660 A1
(43) Pub. Date: Oct. 16, 2025

(54) METHOD FOR MANUFACTURING SEMICONDUCTOR DEVICE AND SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Keiko KAWAMURA, Yokohama Kanagawa (JP); Kentaro ICHINOSEKI, Higashimurayama Tokyo (JP); Tatsuya NISHIWAKI, Yokohama Kanagawa (JP)

(21) Appl. No.: 18/830,433

(22) Filed: Sep. 10, 2024

(30) Foreign Application Priority Data
Apr. 12, 2024 (JP) 2024-064889

(51) Int. Cl. H01L 29/78; H01L 29/40; H01L 29/66

(52) U.S. Cl. CPC H10D 30/668; H10D 30/0297; H10D 64/117

(57) ABSTRACT

A method for manufacturing a semiconductor device includes forming a trench and a mesa part in a semiconductor layer; forming a field plate electrode inside the trench with a field insulating film interposed; forming a silicon nitride film on the field plate electrode, on the mesa part, and on an upper sidewall of the mesa part adjacent to the trench above the field plate electrode; forming a silicon oxide film by chemical vapor deposition inside the trench and on the mesa part; exposing the silicon nitride film on the mesa part by removing the silicon oxide film on the mesa part by chemical mechanical polishing; removing the silicon nitride film on the upper sidewall of the mesa part and the silicon nitride film on the mesa part; and forming a gate electrode on the silicon oxide film inside the trench.

### CROSS-REFERENCE TO RELATED APPLICATION

This application is based upon and claims the benefit of priority from Japanese Patent Application No. 2024-064889, filed on Apr. 12, 2024; the entire contents of which are incorporated herein by reference.

### FIELD

Embodiments described herein relate generally to a method for manufacturing a semiconductor device and a semiconductor device.

### BACKGROUND

There is a configuration of a power device in which a field plate electrode is located inside a trench, and a gate electrode is located on the field plate electrode with an insulating layer interposed.

### BRIEF DESCRIPTION OF THE DRAWINGS

FIG. 1 is a schematic cross-sectional view of a semiconductor device of an embodiment; and

FIG. 2A to FIG. 7B are schematic cross-sectional views showing a method for manufacturing the semiconductor device of the embodiment.

### DETAILED DESCRIPTION

According to one embodiment, a method for manufacturing a semiconductor device includes forming a trench and a mesa part in a semiconductor layer, the mesa part being adjacent to the trench; forming a field plate electrode inside the trench with a field insulating film interposed; forming a silicon nitride film on the field plate electrode, on the mesa part, and on an upper sidewall of the mesa part adjacent to the trench above the field plate electrode; forming a silicon oxide film by chemical vapor deposition inside the trench and on the mesa part after the forming of the silicon nitride film; exposing the silicon nitride film on the mesa part by removing the silicon oxide film on the mesa part by chemical mechanical polishing; removing the silicon nitride film on the upper sidewall of the mesa part and the silicon nitride film on the mesa part after the removing of the silicon oxide film on the mesa part; and forming a gate electrode on the silicon oxide film inside the trench after the removing of the silicon nitride film.

Exemplary embodiments will now be described with reference to the drawings. Similar components in the drawings are marked with like reference numerals. In the drawings below, directions are indicated by an X-axis, a Y-axis, and a Z-axis. A direction along the X-axis is taken as a first direction X. A direction along the Y-axis is taken as a second direction Y; and the second direction Y is orthogonal to the first direction X. A direction along the Z-axis is taken as a third direction Z; and the third direction Z is orthogonal to the first and second directions X and Y. In the specification, a thickness in a specific direction refers to the maximum thickness in the specific direction.

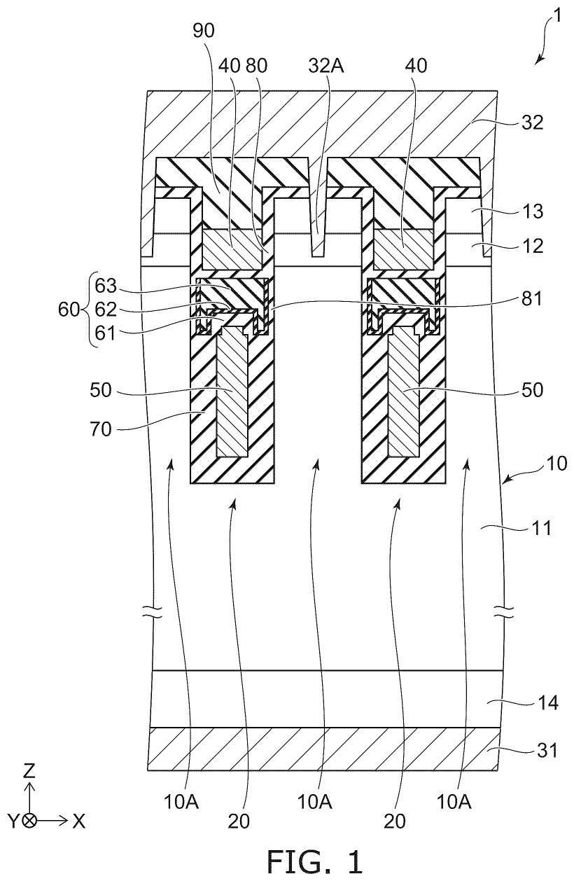

As shown in FIG. 1, a semiconductor device 1 of an embodiment includes a first electrode 31, a second electrode 32, and a semiconductor layer 10 located between the first electrode 31 and the second electrode 32 in the third direction Z. The semiconductor device 1 has, for example, a MOSFET (Metal-Oxide-Semiconductor Field Effect Transistor) structure. The first electrode 31 is a drain electrode of the MOSFET; and the second electrode 32 is a source electrode of the MOSFET. For example, a positive potential is applied to the first electrode 31; and 0 V is applied to the second electrode 32. In an on-state in which the gate voltage of a gate electrode 40, which is described below, is set to be greater than a threshold voltage, a current flows in the vertical direction (the third direction Z) between the first electrode 31 and the second electrode 32 via the semiconductor layer 10. In the third direction Z, the direction from the first electrode 31 toward the second electrode 32 is taken as up or above, and the direction from the second electrode 32 toward the first electrode 31 is taken as down or below.

The semiconductor layer 10 is, for example, a silicon layer. In the semiconductor layer 10 in the specification, a first conductivity type is taken to be an n-type; and a second conductivity type is taken to be a p-type. The first conductivity type may be the p-type; and the second conductivity type may be the n-type.

The semiconductor layer 10 includes an n-type first semiconductor layer 11, a p-type second semiconductor layer 12 located on the first semiconductor layer 11, and an n-type third semiconductor layer 13 located on the second semiconductor layer 12. The n-type impurity concentration of the third semiconductor layer 13 is greater than the n-type impurity concentration of the first semiconductor layer 11. The semiconductor layer 10 also includes an n-type fourth semiconductor layer 14 located between the first electrode 31 and the first semiconductor layer 11. The fourth semiconductor layer 14 contacts the first electrode 31 and is electrically connected with the first electrode 31.

The semiconductor device 1 may be an IGBT (Insulated Gate Bipolar Transistor) that includes a p-type fourth semiconductor layer 14 located between the first electrode 31 and the first semiconductor layer 11. In the IGBT, an n-type buffer layer that has a higher n-type impurity concentration than the first semiconductor layer 11 may be located between the n-type first semiconductor layer 11 and the p-type fourth semiconductor layer 14.

The semiconductor layer 10 includes multiple mesa parts 10A arranged in the first direction X. For example, the mesa part 10A extends in the second direction Y. The mesa part 10A includes a portion of the first semiconductor layer 11, the second semiconductor layer 12 located on the portion of the first semiconductor layer 11, and the third semiconductor layer 13 located on the second semiconductor layer 12.

The semiconductor device 1 includes multiple trench structure parts 20 arranged in the first direction X. For example, the trench structure parts 20 extend in the second direction Y. The trench structure parts 20 are adjacent to the mesa parts 10A in the first direction X.

The trench structure part 20 includes the gate electrode 40, a gate insulating film 80, a field plate electrode 50, a first insulating layer 60, and a field insulating film 70.

The side surface of the gate electrode 40 faces the second semiconductor layer 12 in the first direction X via the gate insulating film 80. The gate electrode 40 extends in the second direction Y; and, for example, an end portion in the second direction Y of the gate electrode 40 is connected to a gate wiring part (not illustrated). In the on-state in which the gate voltage of the gate electrode 40 is set to be greater than the threshold voltage, an n-channel (an inversion layer) is formed in the region of the second semiconductor layer 12 facing the gate electrode 40.

The gate insulating film 80 is positioned between the gate electrode 40 and the second semiconductor layer 12 in the first direction X. The gate insulating film 80 is, for example, a silicon oxide film.

The field plate electrode 50 is positioned below the gate electrode 40 in the third direction Z. The field plate electrode 50 extends in the second direction Y; and, for example, an end portion in the second direction Y of the field plate electrode 50 is connected to the second electrode 32. The field plate electrode 50 can relax the vertical electric field (the electric field in the third direction Z) generated in the semiconductor layer 10; and the breakdown voltage of the semiconductor device 1 can be increased. The field plate electrode 50 may be electrically connected with the gate electrode 40.

The first insulating layer 60 is located between the field plate electrode 50 and the gate electrode 40 in the third direction Z. The first insulating layer 60 includes a first silicon oxide film 61, a silicon nitride film 62, and a second silicon oxide film 63.

The first silicon oxide film 61 is located between the field plate electrode 50 and the silicon nitride film 62 in the third direction Z. The silicon nitride film 62 is located between the first silicon oxide film 61 and the second silicon oxide film 63 in the third direction Z. The second silicon oxide film 63 is located between the silicon nitride film 62 and the gate electrode 40 in the third direction Z. The thickness in the third direction Z of the silicon nitride film 62 positioned between the first silicon oxide film 61 and the second silicon oxide film 63 is less than the thickness in the third direction Z of the second silicon oxide film 63. The thickness in the third direction Z of the silicon nitride film 62 may be less than the thickness in the third direction Z of the first silicon oxide film 61.

A third silicon oxide film 81 is located between the first insulating layer 60 and the mesa part 10A in the first direction X. The silicon nitride film 62 is located between the second silicon oxide film 63 and the third silicon oxide film 81 in the first direction X. The third silicon oxide film 81 is located between the silicon nitride film 62 and the mesa part 10A in the first direction X.

The field insulating film 70 is located between the field plate electrode 50 and the first semiconductor layer 11 in the first and third directions X and Z. The field insulating film 70 is a silicon oxide film and does not include silicon nitride. Charge traps at the bottom portion of the trench structure part 20, which tends to have a high electric field intensity, can be suppressed because the bottom portion of the trench structure part 20 does not include silicon nitride. As a result, characteristics of the semiconductor device 1 such as the breakdown voltage, etc., do not degrade easily, and a reduction of the reliability over time can be prevented.

The silicon nitride film 62 is positioned between the field insulating film 70 and the second silicon oxide film 63 in the third direction Z in regions adjacent to the two side surfaces in the first direction X of the first silicon oxide film 61. The silicon nitride film 62 covers the two side surfaces in the first direction X of the first silicon oxide film 61. The silicon nitride film 62 includes concave portions at the outer sides (the outer sides in the first direction X) of portions of the silicon nitride film 62 on the first silicon oxide film 61.

The second electrode 32 is located on the semiconductor layer 10. For example, the second electrode 32 contacts the third semiconductor layer 13 by a trench contact structure. A portion (a contact portion) 32A of the second electrode 32 extends through the third semiconductor layer 13 and reaches the second semiconductor layer 12. The third semiconductor layer 13 and the second semiconductor layer 12 contact the portion 32A of the second electrode 32 and are electrically connected with the second electrode 32. The p-type impurity concentration of the portion of the second semiconductor layer 12 contacting the portion 32A of the second electrode 32 may be greater than the p-type impurity concentration of the portion of the second semiconductor layer 12 in which the channel is formed. The second electrode 32 may contact the upper surface of the third semiconductor layer 13.

A second insulating layer 90 is located between the gate electrode 40 and the second electrode 32 in the third direction Z. The second insulating layer 90 mainly includes, for example, silicon oxide, and may further include, for example, boron, phosphorus, etc.

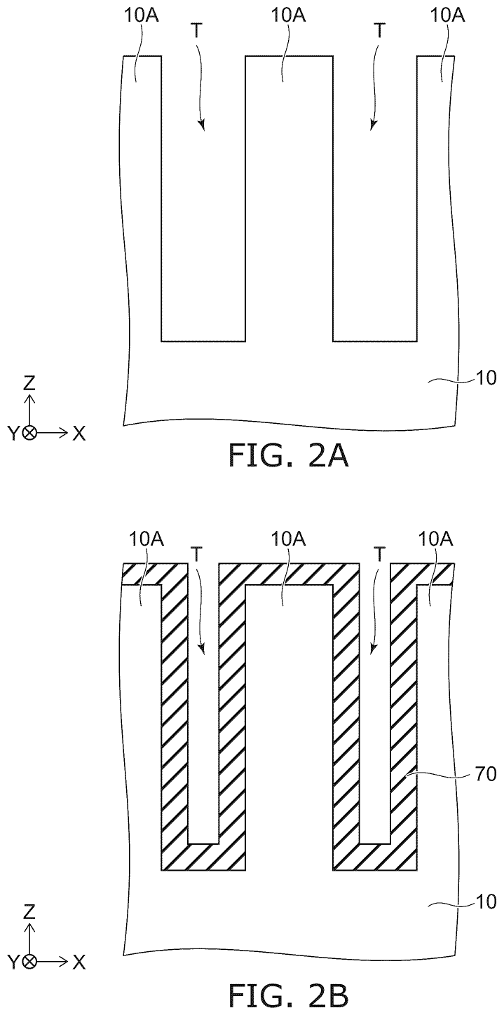

A method for manufacturing the semiconductor device of the embodiment will now be described with reference to FIGS. 2A to 7B. The method for manufacturing the semiconductor device of the embodiment can include the following processes.

As shown in FIG. 2A, multiple trenches T that are arranged in the first direction X are formed in the semiconductor layer 10. For example, the multiple trenches T are formed by RIE (Reactive Ion Etching). By forming the multiple trenches T, the mesa parts 10A are formed in the semiconductor layer 10 between the trenches T adjacent to each other in the first direction X.

After forming the trench T and the mesa part 10A in the semiconductor layer 10, the field insulating film 70 is formed inside the trench T as shown in FIG. 2B. For example, a silicon oxide film can be formed by chemical vapor deposition (CVD) as the field insulating film 70. The field insulating film 70 may be formed by thermal oxidation. The field insulating film 70 is continuously formed on the inner wall (the sidewall and the bottom surface) of the trench T and on the upper surface of the mesa part 10A.

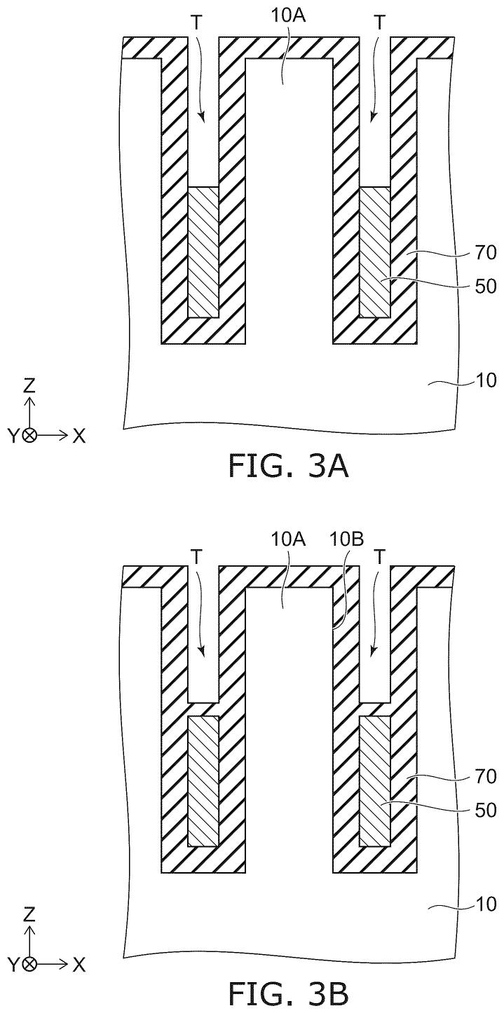

After forming the field insulating film 70, an electrode material used to form the field plate electrode 50 is filled into the trench T with the field insulating film 70 interposed. For example, the electrode material is filled into the trench T by CVD. The electrode material also is deposited on the field insulating film 70 formed on the mesa part 10A. The upper surface of the electrode material inside the trench T is caused to recede by isotropic or anisotropic etching. The electrode material that is formed on the mesa part 10A also is removed. As a result, as shown in FIG. 3A, the electrode material remains as the field plate electrode 50 at the bottom portion side of the trench T.

For example, amorphous silicon or polycrystalline silicon doped with phosphorus or boron can be used as the material of the field plate electrode 50. For example, phosphorus or boron can be doped when forming polycrystalline silicon inside the trench T. Or, phosphorus or boron may be implanted into the polycrystalline silicon by ion implantation after forming the polycrystalline silicon inside the trench T. Or, phosphorus may be diffused into the polycrystalline silicon by high-temperature heat treatment including POCl₃.

After forming the field plate electrode 50, the upper portion of the field plate electrode 50 is oxidized as necessary. For example, the upper portion of the field plate electrode 50 is oxidized by thermal oxidation. This process may not be performed.

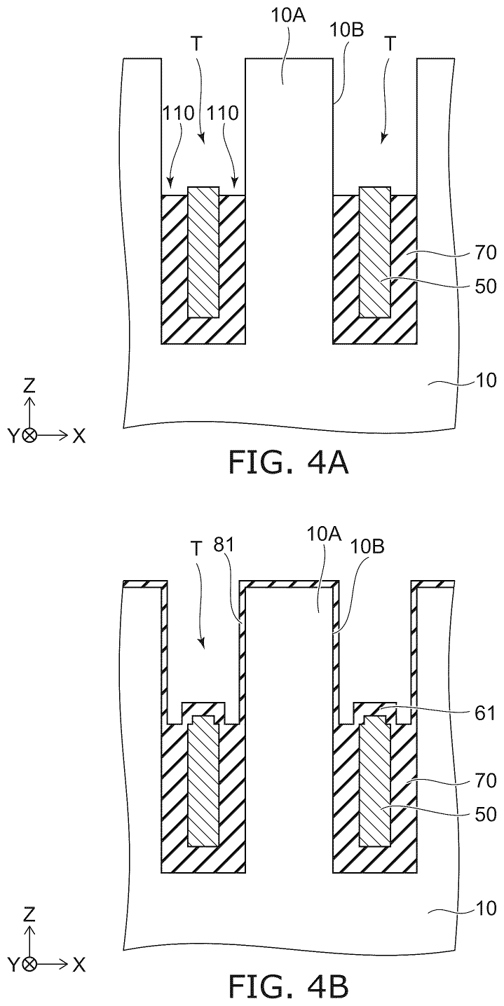

After forming the field plate electrode 50, the field insulating film 70 that is formed on an upper sidewall 10B of the mesa part 10A is removed. The upper sidewall 10B of the mesa part 10A is adjacent to the upper portion of the trench T positioned higher than the field plate electrode 50. For example, the field insulating film 70 that is formed on the upper sidewall 10B of the mesa part 10A is removed by wet etching or isotropic dry etching. As shown in FIG. 4A, the field insulating film 70 that is on the mesa part 10A and on the field plate electrode 50 also is removed.

As shown in FIG. 4A, the field insulating film 70 that contacts the side surface and lower end of the field plate electrode 50 remains inside the trench T.

After the process shown in FIG. 3A, the field insulating film 70 of the upper sidewall 10B and the field insulating film 70 on the mesa part 10A may be removed without oxidizing the upper portion of the field plate electrode 50.

The depth of a recess 110 can be reduced by oxidizing the upper portion of the field plate electrode 50 and then removing the field insulating film 70 of the upper sidewall 10B and the field insulating film 70 on the mesa part 10A.

After removing the field insulating film 70 on the upper sidewall 10B, on the mesa part 10A, and on the field plate electrode 50, the upper sidewall 10B is thermally oxidized, and the third silicon oxide film 81 is formed at the upper sidewall 10B as shown in FIG. 4B. The upper portion of the field plate electrode 50 also is thermally oxidized, and the first silicon oxide film 61 is formed on the field plate electrode 50. The upper surface of the mesa part 10A also is thermally oxidized, and the third silicon oxide film 81 also is formed on the mesa part 10A.

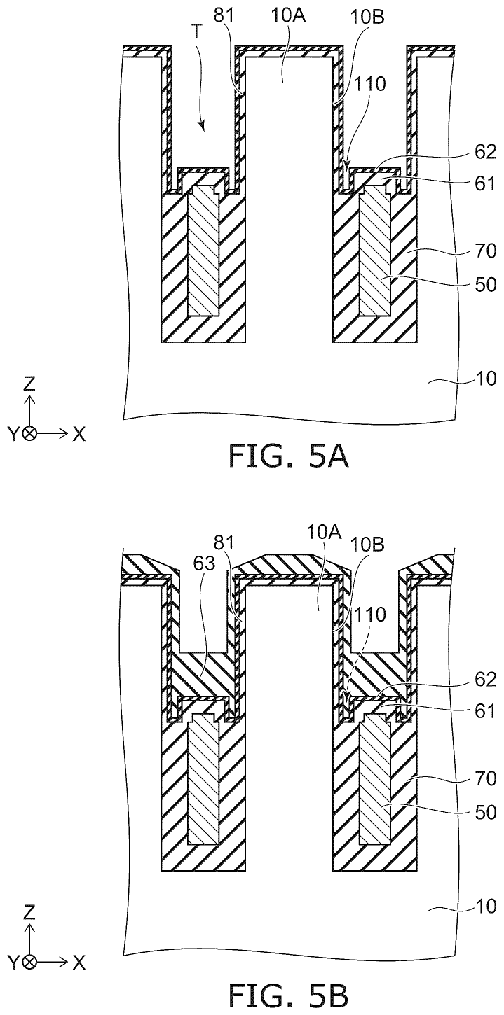

After forming the third silicon oxide film 81, the silicon nitride film 62 is formed by, for example, CVD as shown in FIG. 5A. The silicon nitride film 62 is continuously formed on the upper surface of the first silicon oxide film 61 on the field plate electrode 50, on the third silicon oxide film 81 on the mesa part 10A, on the third silicon oxide film 81 of the upper sidewall 10B, and on the inner surfaces of the recesses 110 including the two side surfaces in the first direction X of the first silicon oxide film 61.

After forming the silicon nitride film 62, the second silicon oxide film 63 is formed by chemical vapor deposition inside the trench T and on the mesa part 10A as shown in FIG. 5B. For example, the second silicon oxide film 63 is formed by HDP-CVD (High Density Plasma Chemical Vapor Deposition) using high-density plasma.

The second silicon oxide film 63 is formed on the silicon nitride film 62 that is on the first silicon oxide film 61, inside the recesses 110, on the silicon nitride film 62 of the upper sidewall 10B, and on the silicon nitride film 62 that is on the mesa part 10A.

By forming the second silicon oxide film 63 by chemical vapor deposition, the film thickness (the film thickness in the first direction X) of the second silicon oxide film 63 formed on the upper sidewall 10B of the mesa part 10A can be less than the film thickness (the film thickness in the third direction Z) of the second silicon oxide film 63 formed on the field plate electrode 50 and the film thickness (the film thickness in the third direction Z) of the second silicon oxide film 63 formed on the upper surface of the mesa part 10A. In other words, the film thickness of the second silicon oxide film 63 formed on the field plate electrode 50 can be increased while suppressing the film thickness of the second silicon oxide film 63 formed on the sidewall inside the trench T.

When forming the second silicon oxide film 63, the portion of the second silicon oxide film 63 deposited on the mesa part 10A that is proximate to the opening of the trench T is easily etched, and the film thickness (the film thickness in the third direction Z) of the second silicon oxide film 63 deposited on the mesa part 10A is thickest at the center vicinity in the first direction X of the mesa part 10A.

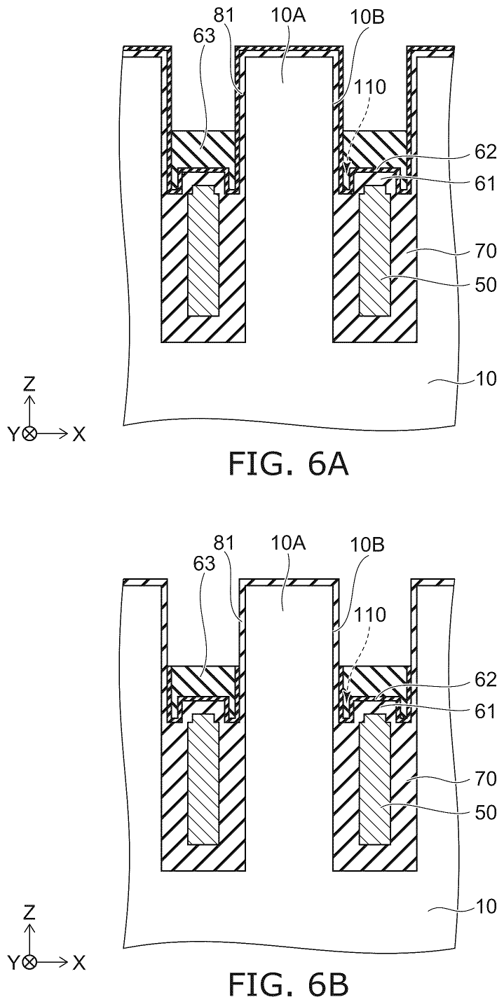

After forming the second silicon oxide film 63, the second silicon oxide film 63 that is on the mesa part 10A is removed by chemical mechanical polishing (CMP). As shown in FIG. 6A, the silicon nitride film 62 that is on the mesa part 10A is exposed thereby. The silicon nitride film 62 that is formed on the mesa part 10A functions as a stopper when removing the second silicon oxide film 63 on the mesa part 10A by CMP. The CMP of the second silicon oxide film 63 is stopped when the silicon nitride film 62 on the mesa part 10A is exposed. The silicon nitride film 62 that is used as the stopper of the CMP is not formed at the bottom portion of the trench T, and so charge traps at the bottom portion of the trench T can be suppressed.

After removing the second silicon oxide film 63 on the mesa part 10A by CMP, the second silicon oxide film 63 that remains on the silicon nitride film 62 of the upper sidewall 10B is removed by, for example, wet etching or isotropic dry etching. As shown in FIG. 6A, the silicon nitride film 62 of the upper sidewall 10B is exposed thereby. By forming the second silicon oxide film 63 so that the film thickness of the second silicon oxide film 63 on the field plate electrode 50 is greater than the film thickness of the second silicon oxide film 63 of the upper sidewall 10B, the second silicon oxide film 63 of the upper sidewall 10B can be removed while causing the second silicon oxide film 63 on the field plate electrode 50 to remain.

After removing the second silicon oxide film 63 on the mesa part 10A and the second silicon oxide film 63 of the upper sidewall 10B, the silicon nitride film 62 that is exposed at the mesa part 10A and the silicon nitride film 62 that is exposed at the upper sidewall 10B are removed. The silicon nitride film 62 is removed using a method such that the etching rate of the silicon nitride film 62 is greater than the etching rate of the silicon oxide film. For example, the silicon nitride film 62 can be removed by isotropic dry etching or wet etching using hot phosphoric acid.

The first silicon oxide film 61 on the field plate electrode 50, the silicon nitride film 62 on the first silicon oxide film 61, the second silicon oxide film 63 on the silicon nitride film 62, the silicon nitride film 62 inside the recess 110, and the second silicon oxide film 63 inside the recess 110 remain.

By removing the silicon nitride film 62 on the mesa part 10A and the silicon nitride film 62 of the upper sidewall 10B, the third silicon oxide film 81 on the mesa part 10A and the third silicon oxide film 81 of the upper sidewall 10B are exposed as shown in FIG. 6B.

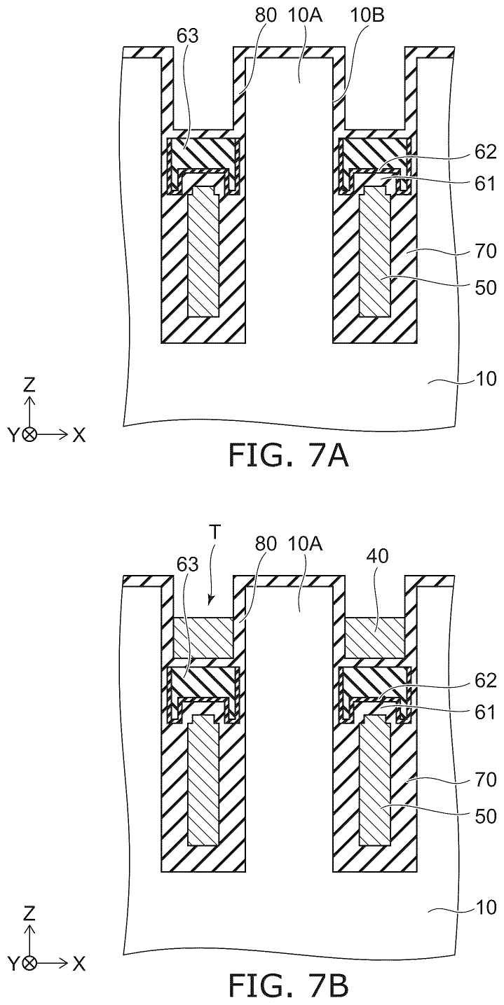

For example, the gate insulating film 80 is formed on the upper sidewall 10B as shown in FIG. 7A by forming an additional silicon oxide film on the third silicon oxide film 81 of the upper sidewall 10B by CVD. In such a case, the gate insulating film 80 includes the third silicon oxide film 81 formed by thermal oxidation and the silicon oxide film formed by CVD. The silicon oxide film that is formed by CVD also is formed on the second silicon oxide film 63.

Or, the third silicon oxide film 81 that remains on the upper sidewall 10B may be used as the gate insulating film 80 as-is. In such a case, the gate insulating film 80 is a single-layer film of the third silicon oxide film 81.

Or, the gate insulating film 80 may be formed on the upper sidewall 10B by thermal oxidation after using etching to remove the third silicon oxide film 81 remaining on the upper sidewall 10B.

After forming the gate insulating film 80, the gate electrode 40 is formed on the second silicon oxide film 63 inside the trench T as shown in FIG. 7B.

For example, a gate electrode material is filled into the trench T by CVD. The gate electrode material also is deposited on the mesa part 10A. The upper surface of the gate electrode material inside the trench T is caused to recede by isotropic or anisotropic etching. The gate electrode material that is formed on the mesa part 10A also is removed. As a result, as shown in FIG. 7B, the gate electrode 40 remains on the second silicon oxide film 63 inside the trench T.

For example, amorphous silicon or polycrystalline silicon doped with phosphorus or boron can be used as the material of the gate electrode 40. For example, the polycrystalline silicon can be doped with phosphorus or boron when forming inside the trench T. Or, phosphorus or boron may be implanted into the polycrystalline silicon by ion implantation after forming the polycrystalline silicon inside the trench T. Or, phosphorus may be diffused into the polycrystalline silicon by high-temperature heat treatment including POCl₃. A metal may be used as the material of the gate electrode 40.

After forming the gate electrode 40, a process of forming the second semiconductor layer 12 and the third semiconductor layer 13 in the semiconductor layer 10 by, for example, ion implantation is performed. Then, the formation may continue with the formation of the second insulating layer 90 and the formation of the second electrode 32.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor device, the method comprising:
forming a trench and a mesa part in a semiconductor layer, the mesa part being adjacent to the trench;
forming a field plate electrode inside the trench with a field insulating film interposed;
forming a silicon nitride film on the field plate electrode, on the mesa part, and on an upper sidewall of the mesa part adjacent to the trench above the field plate electrode;
forming a silicon oxide film by chemical vapor deposition inside the trench and on the mesa part after the forming of the silicon nitride film;
exposing the silicon nitride film on the mesa part by removing the silicon oxide film on the mesa part by chemical mechanical polishing;
removing the silicon nitride film on the upper sidewall of the mesa part and the silicon nitride film on the mesa part after the removing of the silicon oxide film on the mesa part; and
forming a gate electrode on the silicon oxide film inside the trench after the removing of the silicon nitride film.

2. The method according to claim 1, wherein
in the forming of the silicon oxide film, a film thickness of the silicon oxide film formed on the upper sidewall of the mesa part is less than a film thickness of the silicon oxide film formed on the field plate electrode.

3. The method according to claim 1, further comprising:
oxidizing an upper portion of the field plate electrode before the forming of the silicon nitride film.

4. The method according to claim 1, further comprising:
removing the field insulating film formed on the upper sidewall of the mesa part before the forming of the silicon nitride film.

5. The method according to claim 4, further comprising:
oxidizing the upper sidewall after the removing of the field insulating film of the upper sidewall and before the forming of the silicon nitride film.

6. The method according to claim 1, further comprising:
removing the silicon oxide film formed on the silicon nitride film of the upper sidewall before the removing of the silicon nitride film of the upper sidewall.

7. A semiconductor device, comprising:
a mesa part including
a first semiconductor layer of a first conductivity type,
a second semiconductor layer located on the first semiconductor layer, the second semiconductor layer being of a second conductivity type, and
a third semiconductor layer located on the second semiconductor layer, the third semiconductor layer being of the first conductivity type and having a higher first-conductivity-type impurity concentration than the first semiconductor layer; and
a trench structure part adjacent to the mesa part, the trench structure part including
a gate electrode,
a gate insulating film located between the gate electrode and the second semiconductor layer,
a field plate electrode positioned below the gate electrode,
an insulating layer located between the field plate electrode and the gate electrode, and
a field insulating film located between the field plate electrode and the first semiconductor layer,
the insulating layer including a first silicon oxide film, a silicon nitride film, and a second silicon oxide film,
the first silicon oxide film being located between the field plate electrode and the silicon nitride film,
the silicon nitride film being located between the first silicon oxide film and the second silicon oxide film,
the second silicon oxide film being located between the silicon nitride film and the gate electrode,
a thickness of the silicon nitride film being less than a thickness of the second silicon oxide film,
the field insulating film not including silicon nitride.

8. The device according to claim 7, wherein
the thickness of the silicon nitride film is less than a thickness of the first silicon oxide film.

9. The device according to claim 7, wherein
the silicon nitride film includes a concave portion at an outer side of a portion of the silicon nitride film on the first silicon oxide film.

10. The device according to claim 7, further comprising:
a first electrode; and
a fourth semiconductor layer located between the first electrode and the first semiconductor layer,
the fourth semiconductor layer contacting the first electrode.

11. The device according to claim 10, wherein
the fourth semiconductor layer is of the first conductivity type.

12. The device according to claim 10, wherein
the fourth semiconductor layer is of the second conductivity type.

13. The device according to claim 7, further comprising:
a second electrode contacting the third semiconductor layer,
the field plate electrode being connected with the second electrode.
